(19) United States
(12) Patent Application Publication
(10) Pub. No.: US 2025/0383418 A1
(43) Pub. Date: Dec. 18, 2025

(54) Scan Planning for Imaging Apparatus

(71) Applicant: Siemens Healthineers AG, Forchheim (DE)

(72) Inventors: Bernhard Krauss, Burgthann (DE); Maria Kröll, Erlangen (DE); David Grodzki, Erlangen (DE); Christian Knaus, Erlangen (DE); Dominik Paul, Bubenreuth (DE)

(73) Assignee: Siemens Healthineers AG, Forchheim (DE)

(21) Appl. No.: 19/235,745

(22) Filed: Jun. 12, 2025

(30) Foreign Application Priority Data
Jun. 12, 2024 (DE) 102024205401.1

(51) Int. Cl. G01R 33/565; G01R 33/54

(52) U.S. Cl. CPC G01R 33/56572; G01R 33/546

(57) ABSTRACT

The disclosure relates to a method for acquiring a 3D image of a target area by performing a first acquisition of a first area to obtain a first image. The first image may be corrected for distortion to produce a corrected image. A target area may be defined in the corrected image, followed by one of two steps: either the target area may be mathematically distorted to obtain a distorted target area, and a corresponding distorted outer envelope may be specified; or an outer envelope of the target area may be specified and then mathematically distorted to obtain a distorted outer envelope. A second acquisition area that contains the distorted outer envelope with a predefined tolerance may then be automatically or semi-automatically determined. A second acquisition may be performed on this second acquisition area.

### CROSS REFERENCE TO RELATED APPLICATIONS

This patent application claims priority to German Patent Application No. 102024205401.1, filed Jun. 12, 2024, which is incorporated herein by reference in its entirety.

### BACKGROUND

### Field

The disclosure relates to a method for acquiring a 3D image of a target area, in which a first acquisition of a first acquisition area is performed as a localization scan. In addition, the present disclosure relates to a corresponding imaging apparatus and in particular a magnetic resonance system. In addition, the present disclosure relates to a corresponding computer program or computer-readable medium.

### Related Art

Magnetic resonance (MR) images are reconstructed from recorded raw data under the assumption that the gradient fields that are used for position coding of the signal are perfectly linear. However, due to unavoidable non-linearities in the gradient fields of MR scanners, the reconstructed images can appear distorted, in particular if they are taken near to or at the edge of the scanner's specified imaging volume. By means of an additional correction step (distortion correction), already reconstructed MR images can be mathematically corrected, so that they better represent the scanned object geometry. Such distortion correction methods use the spatial distribution of the gradient fields, also referred to here as gradient field maps, and in particular the non-linear field components, which in turn can be measured or calculated from the geometry of the gradient coils of the MR scanner. A suitable method for distortion correction and its reversal is disclosed, for example, in U.S. Pat. No. 8,054,079 B2.

That is, in a conventional MR reconstruction, in particular anatomical structures away from the isocenter of the MR scanner, are not initially displayed at the positions that they have, in reality, in three-dimensional space. Such distortions can subsequently be corrected by the above-mentioned algorithms, which take the relevant physical effects into account. However, this creates a new difficulty, because if you plan a second scan on the distortion-corrected images of the first scan, in reality, the selected area in distorted coordinates is scanned, so that the scanned area does not correspond to the originally planned area even after correction. Instead, parts of the target anatomy may not be acquired at all.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic illustration of an imaging apparatus according to exemplary embodiments of the disclosure.

FIG. 2 shows a schematic illustration for determining a second acquisition area after defining a target area in a distorted first image, according to exemplary embodiments of the disclosure.

The exemplary embodiments of the present disclosure will be described with reference to the accompanying drawings. Elements, features and components that are identical, functionally identical and have the same effect are—insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure is to ensure that a performed scan always includes the target area planned on distortion-corrected images.

In principle, the planning of a scan could also be performed on images without distortion correction. In this case, the images of the first scan are not anatomically correct, but the marked scan area is acquired completely. Subsequently, a distortion correction could be applied to the images of the second scan. However, this method is confusing for the user, because the images of the second scan that are obtained in this manner are in turn not suitable for the planning of a subsequent scan.

Alternatively, the planning could also be performed with “experience.” Based on experience with similar scan regions in other patients, the target area for the second scan on the distortion-corrected images of the first scan would be enlarged compared to normal planning. In this case, the estimate can be incorrect, especially since this estimate would have to change for different scanners due to their different properties. Thus, relevant anatomy is still cut off, or the planned area is too large, so that the scan takes unnecessarily long.

Therefore, an improved solution to this problem is proposed in accordance with the present disclosure. A corresponding method and a corresponding imaging apparatus are described herein.

In accordance with the disclosure, a method for acquiring a 3D image of a target area is therefore provided. The acquisition of the 3D image can be performed by any imaging modality (for example, an MRI system). The target area is the whole or part of the image acquisition space of the imaging modality. The target area can be selected by a user.

In a first step, a first acquisition of a first acquisition area is performed, whereby a first image is obtained. The first acquisition is, for example, a localization scan, which is intended, for example, to localize a specific anatomical area. This first acquisition can, for example, have a coarser resolution or only consist of a few layers with possibly different orientations. The first acquisition results in a first image, which can consist of a 3D image or one or more 2D images.

Subsequently, a distortion of the first image is corrected corresponding to the method in accordance with the disclosure, whereby a corrected first image is obtained. For example, such a distortion can arise due to non-linearities of the imaging modality. In concrete terms, for example, gradient fields of an MR system have non-linearities that lead to such distortions. For example, due to the distortion a cuboid scan object becomes a structure having curved sides, which becomes a cuboid again due to the correction (corrected first image).

In a further step, a target area (in particular position and spatial extent) is defined in the corrected first image. The target area is therefore defined, for example, around an anatomical target object. This is done in the corrected first image that is obtained by the localization scan.

Then, a distorted outer envelope of a distorted target area is determined in one of the following two ways:
a) Mathematically distorting the target area, whereby a distorted target area is obtained. For example, the distortion can be performed in accordance with the displacement vector field, which describes an inverse of the distortion correction during the first acquisition. Under certain circumstances, however, the distortion can also be performed directly in accordance with previously known distortions or non-linearities. In a subsequent step, a distorted outer envelope or surface geometry of the distorted target area is specified. In other words, the distorted target area has a distorted outer envelope, which is specified subsequently.
b) specifying an outer envelope of the target area and mathematically distorting the outer envelope, whereby a distorted outer envelope is obtained. In this advantageous variant, the distortion is only applicable to the outer envelope of the original target area, which can save computing capacity.

Furthermore, a second acquisition area is automatically or semi-automatically determined, which contains the distorted outer envelope of the distorted target area or the distorted target area itself, with a predefined tolerance. The automatic determination of the second acquisition area means that it is determined fully automatically under the condition that the distorted outer envelope of the distorted target area is included with a given tolerance. For example, the tolerance means that only a predominant part of the outer envelope, for example 90%, must be included in the second acquisition area. However, the tolerance can also mean that the second acquisition area is selected to be so large that at least the distorted target area is completely included. A corresponding algorithm can automatically determine the second acquisition area with this tolerance specification. Alternatively, the determination can also be performed in a semi-automatic manner, for example by only visualizing a proposed target area, which is obtained by distorting the original selected target area, but the final second acquisition area must be set by the user themselves. The semi-automatic determination can also refer to the fact that the number of layers of the second acquisition area is manually adapted by a user.

In a final step of the method in accordance with the disclosure, a second acquisition of the second acquisition area is performed. In the second acquisition, the second acquisition area, which was previously determined automatically or semi-automatically, is thus acquired using the respective imaging modality. In this manner, it is possible to ensure that the second acquisition area contains the target area with the desired tolerance.

The method in accordance with the disclosure is particularly advantageously suitable for thin-layer volume scans in which a 3D distortion correction is possible and the coverage of the entire planning volume including the edge areas plays a role.

According to one exemplary embodiment, it is provided that the method is an MR method (magnetic resonance method). As already mentioned, in MR methods, non-linearities usually occur in the gradient fields, which lead to corresponding distortions. Similar distortions can also arise with other imaging methods. Here, too, the distortions can be handled with the method in accordance with the disclosure, insofar as they are distortions that are known in principle and not unwanted image artifacts.

In another exemplary embodiment, the second acquisition area (which would have to be scanned) is automatically determined and visualized together with the target area (which is actually scanned). The visualizations may be made with two differently colored area borders.

In a specific exemplary embodiment, the target area can be changed by means of a user interface, whereupon the second acquisition area is automatically adapted accordingly. The user interface can be a GUI (graphical user interface) or a keyboard or the like. The target area can be changed by graphical dragging and/or by parameter input, etc. With the changed target area, the second acquisition area that results from the distortion can then be automatically determined and visualized again (automatic adaptation). The visualized second acquisition area may be “frozen” so that the visualized target area can be adapted to the automatically determined second acquisition area. As described, the adaptation can therefore be made manually by the operator—or alternatively, for example, also by a single, confirming user interaction automatically by the system.

In accordance with another exemplary embodiment, it is provided that the second acquisition area is determined using a bounding box. Such a bounding box is a virtual bounding frame that includes, for example, the distorted target area. The bounding box then represents the proposed geometry for a new, cuboidal target area. The adaptation of the target area to the bounding box can be automatic or semi-automatic.

In a further exemplary embodiment, in the automatic determination of the second acquisition area, this is selected to be only so large that an imaging volume of a predefined scanner is not departed, or at least the sides of the target area that are outside the imaging volume are not displaced compared to the original planning. In the automatic determination of the second acquisition area, the physics of the imaging modality is thus also considered. In particular, therefore a second acquisition area, which cannot be acquired by the imaging modality at all since it is too large, is not automatically determined. In this manner, the geometry of the maximum imaging volume is taken into account as an edge area when the second acquisition area is determined.

According to another exemplary embodiment, a warning is output if, in the automatic determination of the second acquisition area, an imaging volume of a predetermined scanner is departed or a specified image quality is not reached. In this manner, it can be achieved that a user can intervene, if necessary, if the practical limits of the image acquisition are not adhered to in the theoretical determination of the second acquisition area, or if the image quality becomes too poor.

In accordance with a further exemplary embodiment, it is provided that in the automatic determination of the second acquisition area, this is enlarged only by a maximum of a predefined amount in one or more spatial directions with respect to the target area in the corrected first image. This defines a condition in order to restrict the degrees of freedom when determining the second acquisition area. If, for example, a target area is defined in the corrected first image, it can be specified as a condition for determining the second acquisition area that the target area can be enlarged or reduced by a maximum of 2 cm in each direction. The value “2 cm” is of course only an example. It can also be, for example, 0.5 cm or 10 cm or the like. An enlargement or reduction does not have to be possible in all directions. For example, it is sufficient if an enlargement or reduction is only permitted in one or two spatial directions. In this manner, the risk of inappropriate determination of the second acquisition area due to strong local distortions can be reduced.

In a further exemplary embodiment, it is provided that in the automatic determination of the second acquisition area, this is selected so that the surface of the first acquisition area is also included. This is advantageous in particular if, for example, the distortion correction uses the same volume geometry before and after the correction.

In an exemplary embodiment, to perform the second acquisition, a matrix size and/or a layer thickness for the second acquisition area is automatically adapted. The matrix size is defined by the number of reconstructed pixels per layer and is usually adjustable by the user. If a constant minimum spatial resolution is required despite an enlarged image size, the matrix size can be enlarged in accordance with the image size. Similarly, the layer thickness for the second acquisition area can be determined automatically. If necessary, the number of layers can also be increased or reduced if the second acquisition area is significantly larger or smaller than the originally planned target area.

In another exemplary embodiment, the first acquisition area and the second acquisition area are in each case cuboidal. The cuboid shape has the advantage that the layer structure can be defined in a correspondingly simple manner. In addition, a cuboid can be enlarged or reduced relatively easily.

In accordance with a further exemplary embodiment, it is provided that a layer orientation is not automatically changed. Layer orientation is useful for the assessment of the images by the doctor. In an advantageous manner, standardized views would thus be achievable in 2D viewing.

In a further exemplary embodiment, the entire area is first enlarged or reduced and displaced for the automatic or semi-automatic determination of the second acquisition area. Each layer is then repositioned and/or tilted again separately at right angles to the plane in order to approximate the ideal layer position. The target area can thus be divided into sub-target areas and, in particular, into layers, which are initially enlarged or reduced together. The enlarged or reduced layers can then be repositioned or adapted at an angle. This results in a stack of layers or sub-target areas that are scanned separately and, in a good approximation, do not require any distortion correction perpendicular to the layer, which can be useful especially for thick layers. Compared to the original planning, the number of layers can also be retained.

In a still further exemplary embodiment, a third acquisition is performed on the basis of the second acquisition analogously to the above method. This means that the method in accordance with the disclosure can be repeated several times. In the case of repetition, the second acquisition of the first implementation would be the first acquisition of the second implementation and the second acquisition of the second implementation would be the third acquisition. The method can thus be applied to the distortion-corrected images of the second acquisition in order to plan one or more data acquisitions.

The above object is also achieved in accordance with the disclosure by an imaging apparatus for acquiring a 3D image of a target area. The apparatus may include:
an acquisition facility (scanner) for performing a first acquisition (for example, localization scan) of a first acquisition area, whereby a first image is obtained,
a computing facility for correcting a distortion of the first image, whereby a corrected first image is obtained, and
an interface facility for defining a target area in the corrected first image.

The computing facility may be configured to perform one of the following two steps: (1) mathematically distorting the target area to obtain a distorted target area, and specifying a distorted outer envelope of the distorted target area, or (2) specifying an outer envelope of the target area and mathematically distorting the outer envelope to obtain a distorted outer envelope

The computing facility may also be configured to automatically or semi-automatically determine a second acquisition area, which contains the distorted outer envelope of the distorted target area with a predefined tolerance. A second acquisition of the second acquisition area can be performed using the acquisition facility.

The imaging apparatus may include an acquisition facility, which can include an MR unit, for example. It is possible for the acquisition facility to generate a first image from the respectively acquired raw data.

In addition, the imaging apparatus may include a computing facility (e.g., computer) with which it is possible to define the distortion of the first image. For this purpose, the computing facility can have a processor and a storage unit (memory).

Furthermore, the imaging apparatus may include an interface facility with which a user can define a target area. This can be a GUI (Graphical User Interface). In order to define the target area, for example, the first image is displayed on a monitor of the interface facility and the target area is defined thereon using corresponding drawing tools or parameter inputs. The interface facility is coupled to the computing facility in order to transmit the defined target area to the computing facility for the determination of the second acquisition area. The computing facility, in turn, is coupled to the acquisition facility to be able to perform the second acquisition on the basis of the determined second acquisition area.

The advantages and further development possibilities described above in connection with the method in accordance with the disclosure also apply mutatis mutandis to the imaging apparatus in accordance with the disclosure. Accordingly, the method features that are illustrated are to be understood as functional features of the imaging apparatus.

The imaging apparatus can be a magnetic resonance system. In this case, in particular, the non-linearities that result in the gradient field of the magnetic resonance system can be compensated for a meaningful target area scan.

In accordance with the disclosure, a computer program is also provided that comprises commands that, when the program is being executed by the imaging apparatus described above, prompt this imaging apparatus to implement the method that is also described. In the same way, a computer-readable medium is provided that comprises commands that, when executed by the aforementioned imaging apparatus, prompt the imaging apparatus to implement the aforementioned method.

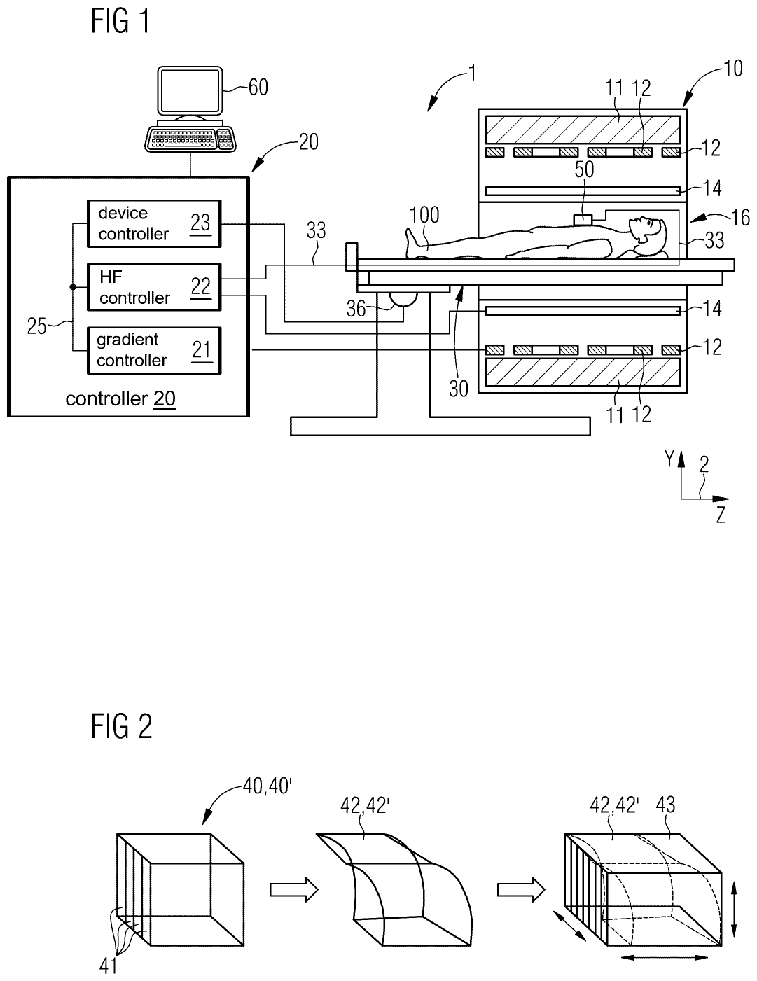

FIG. 1 illustrates a schematic illustration of an embodiment of a magnetic resonance tomograph 1 as an exemplary medical apparatus.

The magnet unit (scanner) 10 has a field magnet 11, which generates a static magnetic field BO for orienting nuclear spins of samples or of the patient 100 in a recording area. The recording area is characterized by an extremely homogeneous static magnetic field BO, wherein the homogeneity relates in particular to the magnetic field strength or the magnitude. The receiving region is almost spherical and arranged in a patient tunnel 16, which extends in a longitudinal direction 2 through the magnet unit 10. A patient couch 30 can be moved in the patient tunnel 16 by the positioning unit 36. Usually, the field magnet 11 is a superconducting magnet that can provide magnetic fields with a magnetic flux density of up to 3T, in the case of the latest devices even above this. However, permanent magnets or electromagnets having normally conducting coils can also be used for lower magnetic field strengths.

To maintain the low temperatures of the superconducting magnet coils, the superconducting magnet requires a cooling unit with a relatively high-power consumption and an equally high waste heat and thus cooling requirements.

Furthermore, the magnet unit 10 has gradient coils 12, which are designed so as to superimpose temporally and spatially variable magnetic fields in three spatial directions on the magnetic field BO in order to spatially differentiate the mapping regions that are acquired in the examination volume. The gradient coils 12 are usually coils of normally conducting wires that can generate mutually orthogonal fields in the examination volume.

The normally conductive gradient coils 12 are also driven by a gradient controller 21 with very high currents and have a corresponding need for electrical energy, power and cooling requirement for the waste heat.

The magnet unit 10 further has a body coil 14, which is configured so as to emit a high-frequency signal, which is supplied via a signal line, into the examination volume and so as to receive resonance signals, which are emitted by the patient 100, and so as to emit the resonance signals via a signal line. The magnet unit 10 may also be referred to as an acquisition facility or scanner.

A control unit (controller) 20 supplies the magnet unit 10 with the various signals for the gradient coils 12 and the body coil 14 and evaluates the received signals. The controller 20 may include a gradient controller 21, a high-frequency (HF) unit (HF controller, generator) 22, and/or a device controller 23. The controller 20 may include processing circuitry that is configured to perform one or more functions and/or operations of the controller 20. Additionally, or alternatively, one or more components of the controller 20 (e.g., gradient controller 21, HF unit 22, and/or device controller 23) may include processing circuitry that is configured to perform one or more respective functions and/or operations of the component(s). The controller 20 (and/or one or more components therein) may include one or more memory units that are configured to store data and/or instructions, where the instructions may be executed by the processing circuitry to perform the various functions and/or operations of the controller 20.

The gradient controller 21 may be configured to supply the gradient coils 12 with variable currents via supply lines, which provide the desired gradient fields in the examination volume in a temporally coordinated manner.

The high-frequency (HF) unit (HF controller, generator) 22 may be configured to generate a high-frequency pulse having a predetermined temporal profile, amplitude and spectral power distribution for exciting a magnetic resonance of the nuclear spins in the patient 100. In this case, pulse powers in the range of kilowatts can be achieved. The excitation signals can be emitted into the patient 100 via the body coil 14 or also via a local transmitting antenna.

The device controller 23 may be configured to communicate via a signal bus 25 with the gradient controller 21 and/or the HF unit 22, and be configured to control the gradient controller 21 and/or HF unit 22.

In order to receive the magnetic resonance signal, a local coil 50 in accordance with the disclosure may be arranged on the patient 100 in the patient tunnel 16 to detect magnetic resonance signals from an examination zone in the immediate vicinity with the largest possible signal-to-noise ratio. The local coil 50 is in signal connection with a receiver in the high-frequency unit 22 via a connecting line 33.

Furthermore, the magnetic resonance tomograph 1 optionally has a computing facility 60, which can be used for a superordinate control of the control unit 20 and/or for data evaluation. The computing facility 60 may be a computer with one or more input/output interfaces.

Furthermore, the magnetic resonance tomograph 1 optionally has an interface, for example, to a data network, via which the device controller 23 can communicate with a supply controller of a supply facility, for example, send messages and receive instructions.

Typically, the gradient fields of MR systems are characterized by non-linearities, which ensure corresponding distortions during image reconstruction. In the case of other imaging modalities, effects can also occur, which also lead to distortions in the image reconstruction. Nevertheless, it is possible with the method in accordance with the disclosure to always parameterize an image acquisition or a scan in such a manner that it always includes the target area that is planned on distortion-corrected images. For this purpose, it can be assumed that the distortion as well as a correction for this are mathematically known. The distortion in the mathematical sense is the inversion of the distortion correction.

Furthermore, a clear distortion correction should be possible in the relevant imaging volume.

Now a first scan or a first acquisition can be performed as a localization scan. For this purpose, a first detection area is defined, which is, for example, cuboidal. After reconstruction, the first acquisition results in a first image, which is usually distorted due to non-linearities. This distortion is corrected with a distortion correction, as is known, for example, from the publication U.S. Pat. No. 8,054,079 B2. After the correction, a corrected first image results.

It is possible to define a target area 40 in the corrected first image, which is illustrated in FIG. 2. This target area 40 can be cuboidal. In addition, it can be constructed in layers 41, as are customary in MR detection. The target area includes the space or the objects that are of importance to the user. Therefore, the target area should be completely covered (if necessary with a selected tolerance) during the second acquisition (second scan).

The target area 40 is then mathematically distorted. The distortion can be known to the system, or it results as an inverse of the distortion correction. The distortion of the target area 40 leads to the distorted target area 42. For example, during distortion, the sides of the target area are curved. If necessary, all sides are curved or only part of them. The shape or distorted outer envelope 42′ of the target area after the distortion, i.e. the shape or structure of the distorted target area 42, is specified. In particular, the geometry of this distorted outer envelope 42′ is determined. The computational effort can be reduced if the outer envelope 40′ is first specified by the target area 40 and this is mathematically distorted. The result would then again be the distorted outer envelope 42′.

In a subsequent step, a second acquisition area 43 is determined automatically or semi-automatically. The second acquisition area 43 is to contain the distorted outer envelope 42′ of the distorted target area 42 with a predefined tolerance. The tolerance can be selected such that the second acquisition area completely includes the distorted target area 42 or the distorted outer envelope 42′. Alternatively, the tolerance could also be selected such that the second acquisition area 43 includes only 90% or 95% of the distorted target area 42.

In an exemplary embodiment, the shape of the original target area 40 (cuboid in the example of FIG. 2) is retained for the second acquisition area 43. In this way, the original target area 40 or the cuboid can be stretched, compressed and displaced. In any case, it should be changed in such a way that it encloses the distorted target area 42 or its outer envelope 42′ (with a respective tolerance). Thus, in the case of an MR system, the new target area, i.e. the second acquisition area 43, remains scannable without changes in the sequence code.

The corresponding scan parameters are specified automatically or manually so that the sequence used is executable and provides an acceptable image quality. These scanning parameters include, for example, field of view, position of the layers, number of layers, repetition time TR, size of the image matrix, etc.

The second acquisition or the second scan is performed with these parameters. Optionally, a distortion correction is then performed, and also optionally, the image volume is then limited to the originally planned target area 40.

When determining the second acquisition area 43, it may be advantageous to exclude parts of the distorted outer envelope 42′ of the distorted target area 42, for example, if they lie outside the imaging volume of the MR scanner. This imaging volume is specified, inter alia, by the size of the homogeneity volume of the main magnetic field of the system. Otherwise, if this boundary condition is not met, the volume is increased unnecessarily, since the affected areas cannot be displayed anyway. A limitation of the enlargement is also conceivable as a safety measure, such that, for example, the target area is enlarged by a maximum of 2 cm in each direction.

When determining the second acquisition area 43, it may also be expedient to enlarge the target area 40 for the second scan such that not only the distorted outer envelope 42′ of the target area, or the distorted target area 42, but also the original outer envelope 40′ of the target area 40 is included. This is useful if, for example, the distortion correction uses the same geometric volume before and after correction.

With regard to the adaptation of the scan parameters, it can be useful, in addition to the obvious parameters for describing the enlarged volume, to also automatically adapt, for example, the matrix size and the layer thickness for the actually scanned area. This is recommended if an acceptable image quality is not otherwise achieved. The need for this can be assessed, for example, by looking at extreme cases, i.e. regions within the target area with particularly large compression or extension on the basis of the distortion. For example, a matrix size 128×128 may no longer be sufficient for sufficient image quality in an enlarged second acquisition area, provided that the mapping scale is locally retained at at least one point during the distortion; in such a case, for example, a matrix size of 156×156 is selected. The layer thickness can be adapted if, after the distortion of the target area, sites with layers that are too thin or too thick are formed.

The method, as disclosed, is particularly easy to use when cuboidal scan regions are employed but is not limited thereto. In this case, for example, to specify the second acquisition area 43, the distorted target area 42 or the distorted outer envelope 42′ can be surrounded by a bounding box, the sides of which are displaced inward or outward with respect to the original planning. Specifying new scan parameters is relatively easy in this case.

When specifying the scan parameters, it should be noted that the layer orientation of the actually scanned images in the clinical environment should usually correspond to the original planning for the second scan in order to enable standardized views in 2D viewing, for example in a PACS (Picture Archiving and Communication System). On the other hand, the position and size of the layers can be varied or adapted during parameterization.

Under certain circumstances, the present method can also be performed as a first step before a breakdown into sub-volumes (sub-target areas). For example, in the second step after an application of the method, it can be useful to specify individual target areas layer by layer and then to reposition, orient and scan the layers.

In an advantageous manner, it can be achieved with the presented exemplary embodiments that the originally defined scan area is completely covered in the second acquisition. In particular, it can be ensured that the scan parameters are not adapted more than necessary, so that spatial resolution and scan time are largely preserved. In addition, no assumptions have to be made about the target anatomy. The method is therefore robust and intuitively understandable for the user.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first,” “second,” etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments, whether or not explicitly described.

The exemplary embodiments described herein are provided for illustrative purposes and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for acquiring a three-dimensional (3D) image of a target area, the method comprising:
performing a first acquisition of a first acquisition area to obtain a first image;
correcting a distortion of the first image to obtain a corrected first image;
defining a target area in the corrected first image;
obtaining a distorted target area by: (i) mathematically distorting the target area and specifying a distorted outer envelope of the distorted target area, or (ii) specifying an outer envelope of the target area and mathematically distorting the outer envelope;
automatically or semi-automatically determining a second acquisition area containing the distorted outer envelope with a predefined tolerance; and
performing a second acquisition of the second acquisition area.

2. The method as claimed in claim 1, wherein the method is a magnetic resonance (MR) method.

3. The method as claimed in claim 1, wherein the second acquisition area is automatically determined and visualized together with the target area.

4. The method as claimed in claim 3, wherein the target area is changed using a user interface, and the second acquisition area is automatically adapted accordingly.

5. The method as claimed in claim 1, wherein the second acquisition area is determined using a bounding box.

6. The method as claimed in claim 1, wherein the automatic determination of the second acquisition area comprises selecting the second acquisition area to be only as large as to avoid an imaging volume of a predefined scanner form being departed.

7. The method as claimed in claim 1, further comprising outputting a warning in response to, in the automatic determination of the second acquisition area, an imaging volume of a predetermined scanner is departed or a specified image quality is not reached.

8. The method as claimed in claim 1, wherein, in the automatic determination of the second acquisition area, the second acquisition area is enlarged only by a maximum of a predefined amount in one or more spatial directions with respect to the target area in the corrected first image.

9. The method as claimed in claim 1, wherein, in the automatic determination of the second acquisition area, the second acquisition area is selected so that a surface of the first acquisition area is also included.

10. The method as claimed in claim 1, wherein performing the second acquisition comprises automatically adapting a matrix size and/or a layer thickness for the second acquisition area.

11. The method as claimed in claim 1, wherein each of the first acquisition area and the second acquisition area are cuboidal.

12. The method as claimed in claim 1, wherein an originally planned layer orientation for the target area corresponds to a layer orientation when the second acquisition is performed.

13. The method as claimed in claim 1, wherein, after the automatic or semi-automatic determination of the second acquisition area, individual layers are repositioned and/or tilted separately and then scanned.

14. The method as claimed in claim 1, further comprising performing a third acquisition based on the second acquisition.

15. At least one non-transitory computer-readable medium comprising instructions stored thereon, that when executed by one or more processors, cause the one or more processors to perform the method of claim 1.

16. An apparatus comprising:
one or more processors; and
memory storing instructions that, when executed by the one or more processors, cause the apparatus to perform the method of claim 1.

17. An imaging apparatus for acquiring a three-dimensional (3D) image of a target area, the imaging apparatus comprising:
a scanner configured to perform a first acquisition of a first acquisition area to obtain a first image;
a computer configured to correct a distortion of the first image to obtain a corrected first image; and
an interface configured to define a target area in the corrected first image,
wherein the computer is further configured to:
obtain a distorted target image by (i) mathematically distorting the target area and specifying a distorted outer envelope of the distorted target area, or (ii) specifying an outer envelope of the target area and mathematically distorting the outer envelope; and
automatically or semi-automatically determine a second acquisition area that contains the distorted outer envelope of the distorted target area with a tolerance to be predefined; and
wherein the scanner is further configured to perform a second acquisition of the second acquisition area.

18. The imaging apparatus as claimed in claim 17, wherein the imaging apparatus is a magnetic resonance (MR) system.
